(19) United States
(12) Patent Application Publication
(10) Pub. No.: US 2015/0060013 A1
(43) Pub. Date: Mar. 5, 2015

(54) TUNABLE TEMPERATURE CONTROLLED ELECTROSTATIC CHUCK ASSEMBLY

(71) Applicant: APPLIED MATERIALS, INC., SANTA CLARA, CA (US)

(72) Inventor: Douglas A. Buchberger, JR., Livermore, CA (US)

(73) Assignee: APPLIED MATERIALS, INC., SANTA CLARA, CA (US)

(21) Appl. No.: 14/019,290

(22) Filed: Sep. 5, 2013

(51) Int. Cl. H01J 37/32

(52) U.S. Cl. CPC H01J 37/32697; H01J 37/32724
USPC 165/64; 219/201; 156/345.29; 156/345.27

(57) ABSTRACT

Embodiments include a pedestal to support a workpiece during plasma processing with tunable temperature control. In one embodiment, the pedestal includes an electrostatic chuck (ESC) having a top surface over which the workpiece is to be disposed. The pedestal includes one or more heating elements disposed under the top surface of the ESC. The pedestal includes a cooling base disposed under the ESC. The pedestal includes a plurality of compartments disposed between the cooling base and the top surface of the ESC, the plurality of compartments independently controllable to different pressures. One or more controllers independently control pressure in a first of the plurality of compartments to a first pressure and in a second of the plurality of compartments to a second pressure.

### TECHNICAL FIELD

Embodiments of the present invention relate to the microelectronics manufacturing industry and more particularly to temperature-controlled pedestals for supporting a workpiece during plasma processing.

### BACKGROUND

Plasma processing equipment, such as equipment designed to perform plasma etching of microelectronic devices and the like, use electrostatic chucks (ESCs) to support and hold a wafer or substrate in place during processing. Such equipment generally includes heating and/or cooling elements to adjust the temperature of the ESC, and therefore adjust the temperature of the wafer. A variety of factors result in temperature non-uniformities on the wafer, which can result in inconsistent and malfunctioning microelectronic devices. For example, in equipment where a bonding material is used to couple elements of the pedestal (e.g., heating elements, cooling elements, etc.), inconsistencies in the thickness of the bonding material and/or the chemical composition of the bonding material can result in varying thermal conductivities. The varying thermal conductivities can result in hot or cool spots on the ESC, which in turn can result in hot or cool spots on the wafer. Other causes of temperature non-uniformities can include non-uniform heating and cooling of the ESC, varying contact resistance between the wafer and the ESC, plasma load variations, and other temperature variations within the processing chamber (e.g., variations due to the location of doors to the chamber).

Additionally, plasma processing equipment can consume large amounts of power. Some of the power consumption by plasma processing equipment is consumed by cooling and heating mechanisms to maintain a uniform wafer temperature.

### SUMMARY

One or more embodiments of the invention are directed to a temperature-controlled pedestal to support a workpiece during plasma processing.

In one embodiment, the pedestal includes an electrostatic chuck (ESC) having a top surface over which the workpiece is to be disposed. The pedestal includes one or more heating elements disposed under the top surface of the ESC. The pedestal includes a cooling base disposed under the ESC. The pedestal includes a plurality of compartments separated by gas seals and disposed between the cooling base and the one or more heating elements, the plurality of compartments independently controllable to different pressures. One or more controllers independently control pressure in a first of the plurality of compartments to a first pressure and in a second of the plurality of compartments to a second pressure.

In one embodiment, a plasma etch system includes a vacuum chamber, a gas source to supply a gas to the vacuum chamber, a pedestal, and an RF generator coupled to at least one of the vacuum chamber, gas source, or pedestal. The pedestal includes an electrostatic chuck (ESC) having a top surface over which a workpiece is to be disposed. The pedestal includes one or more heating elements disposed under the top surface of the ESC, a cooling base disposed under the ESC. The pedestal includes a plurality of compartments separated by gas seals and disposed between the cooling base and the one or more heating elements, the plurality of compartments independently controllable to different pressures. In one embodiment, the system includes one or more controllers to generate a plurality of temperature zones on the ESC surface based on maintaining a first pressure in a first of the plurality of compartments and a second pressure in a second of the plurality of compartments. The plurality of temperature zones can include an inner circular zone and an outer annular zone. In one embodiment, the system includes one or more temperature sensors disposed above the pedestal to detect a temperature of the workpiece. The one or more controllers is to maintain the first pressure in the first of the plurality of compartments and the second pressure in the second plurality of compartments based on a temperature of the workpiece determined by the one or more temperature sensors.

### BRIEF DESCRIPTION OF THE DRAWINGS

Embodiments of the present invention are illustrated by way of example, and not limitation, in the figures of the accompanying drawings in which:

FIG. 1 is a schematic of a plasma etch system including a pedestal to support a workpiece during plasma processing in accordance with an embodiment of the invention;

FIG. 2 is a cross-sectional diagram of a pedestal to support a workpiece during plasma processing in accordance with an embodiment of the invention;

FIGS. 3A, 3B, and 3C are top down views of exemplary temperature zones on an electrostatic chuck (ESC) surface, in accordance with embodiments of the invention;

FIG. 4 is a top-down view of independently pressure-controllable compartments, in accordance with embodiments of the invention;

FIGS. 5A and 5B are block diagrams illustrating systems with top-down temperature sensors, according to embodiments of the invention;

FIG. 6 is a flow diagram of a method of controlling the temperature of a workpiece during plasma processing according to embodiments of the invention; and

FIG. 7 illustrates a block diagram of an exemplary computer system for performing methods described herein, in accordance with an embodiment of the present invention.

### DETAILED DESCRIPTION

A method, system, and pedestal to control the temperature of a workpiece during plasma processing are described.

In embodiments, an electrostatic chuck (ESC) assembly (also referred to herein as a pedestal) includes multi-zone temperature tunability. Multiple zones enable independent fine tuning of the temperature of areas on the ESC surface, which can compensate for temperature non-uniformities on the workpiece from various sources.

According to one embodiment, the pedestal includes variable thermal conductivity gaps to provide for the multiple temperature zones. The pedestal can include one or more heating elements which provide the heat flux to heat the ESC. According to one such embodiment, the gaps form compartments between the heating element(s) and a surface of a cooling base. The ESC surface temperature pattern can be adjusted based on, for example, the location, shape, and number of compartments, and by adjusting the thermal conductivity of the individual compartments. In one embodiment, a controller independently adjusts the gas pressure in the individual compartments to generate independent temperature zones. In one embodiment, different gases having different thermal conductivities are used to generate different temperature zones on the ESC surface.

In one embodiment, the pedestal includes thermal breaks to minimize cross talk and zone interaction between the individual temperature zones. In one embodiment with thermal breaks that include air gaps, the controller also controls the gas pressure in the thermal breaks. The controller can include, for example, one or more pressure control devices supplying gas to the compartments by means of a multiplexing valve array or a rotary valve assembly. Thus, according to embodiments of the invention, an ESC assembly independently controls gas pressure of multiple compartments located below the ESC and above the cooling base. Embodiments of the invention can—reduce the thermal conductance to the cooling base, thereby requiring less power to maintain any given set point. The lower power levels can result in reduced thermal non-uniformities due to, for example, heating patterns, bonding layer non-uniformities, and cooling channel patterns.

In the following description, numerous details are set forth, however, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment,” or “in one embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention, or only one embodiment. Furthermore, the particular features, structures, functions, or characteristics may be combined in any suitable manner in one or more embodiments. For example, a first embodiment may be combined with a second embodiment anywhere the two embodiments are not specifically denoted as being mutually exclusive.

The term “coupled” is used herein to describe functional or structural relationships between components. “Coupled” may be used to indicated that two or more elements are in either direct or indirect (with other intervening elements between them or through the medium) mechanical, acoustic, optical, or electrical contact with each other, and/or that the two or more elements co-operate or interact with each other (e.g., as in a cause and effect relationship).

The terms “over,” “under,” “between,” and “on” as used herein refer to a relative position of one component or material layer with respect to other components or layers where such physical relationships are noteworthy for mechanical components in the context of an assembly, or in the context of material layers of a micromachined stack. One layer (component) disposed over or under another layer (component) may be directly in contact with the other layer (component) or may have one or more intervening layers (components). Moreover, one layer (component) disposed between two layers (components) may be directly in contact with the two layers (components) or may have one or more intervening layers (components). In contrast, a first layer (component) “on” a second layer (component) is in direct contact with that second layer (component).

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

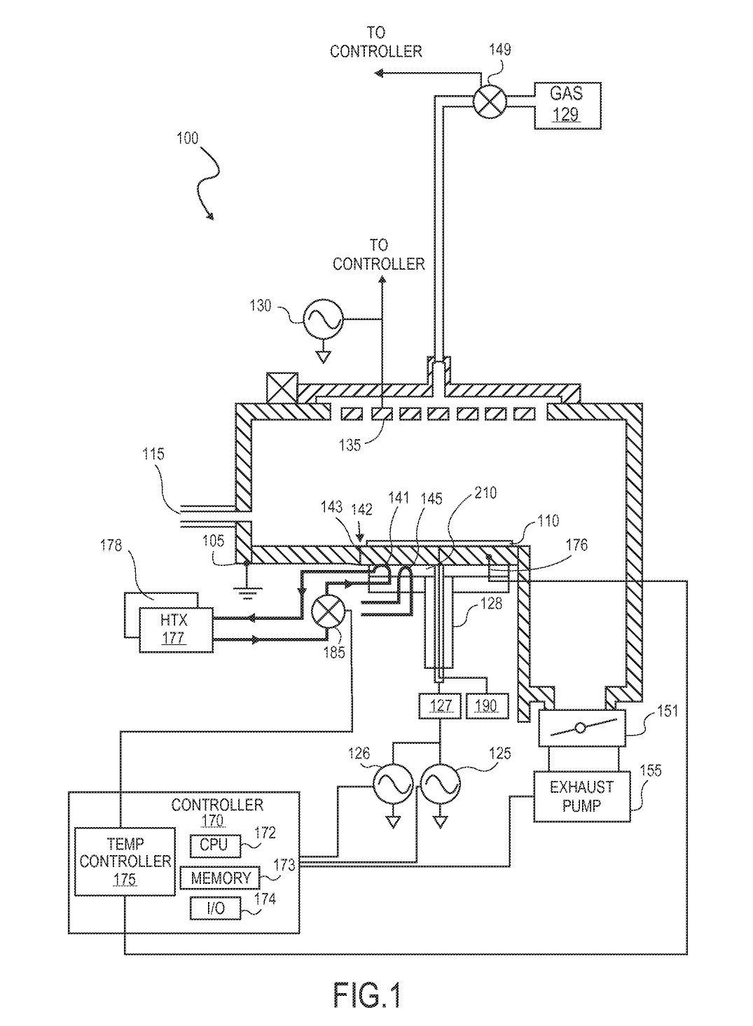

FIG. 1 is a schematic of a plasma etch system 100 including a pedestal 142 in accordance with an embodiment of the present invention. The plasma etch system 100 may be any type of high performance etch chamber known in the art, such as, but not limited to, Enabler™, MxP®, MxP+™, Super-E™, DPS II AdvantEdge™ G3, or E-MAX® chambers manufactured by Applied Materials of CA, USA. Other commercially available etch chambers may similarly utilize the pedestals described herein. While the exemplary embodiments are described in the context of the plasma etch system 100, the pedestal described herein is also adaptable to other processing systems used to perform any plasma fabrication process (e.g., plasma deposition systems, etc.) that places a heat load on a workpiece supported by the pedestal.

Referring to FIG. 1, the plasma etch system 100 includes a vacuum chamber 105, that is typically grounded. A workpiece 110 is loaded through an opening 115 and clamped to a pedestal 142. The pedestal 142 can include independently controllable temperature zones as described herein. The workpiece 110 may be any conventionally employed in the plasma processing art (e.g., semiconductor wafer or other workpiece employed in plasma processing) and the present invention is not limited in this respect. The workpiece 110 is disposed on a top surface of a dielectric material 143 disposed over a cooling base assembly 210. Process (source) gases are supplied from gas source(s) 129 through a mass flow controller 149 to the interior of the chamber 105 (e.g., via a gas showerhead). Chamber 105 is evacuated via an exhaust valve 151 connected to a high capacity vacuum pump stack 155.

When plasma power is applied to the chamber 105, a plasma is formed in a processing region over workpiece 110. A plasma bias power 125 is coupled into the pedestal 142 to energize the plasma. The plasma bias power 125 typically has a low frequency between about 2 MHz to 60 MHz, and may be for example in the 13.56 MHz band. In the exemplary embodiment, the plasma etch system 100 includes a second plasma bias power 126 operating at about the 2 MHz band which is connected to the same RF match 127 as plasma bias power 125 and coupled to a lower electrode via a power conduit 128. A conductor 190 provides DC voltage a ESC clamp electrode disposed in the dielectric layer 143. A plasma source power 130 is coupled through a match (not depicted) to a plasma generating element 135 to provide high frequency source power to inductively or capacitively energize the plasma. The plasma source power 130 may have a higher frequency than the plasma bias power 125, such as between 100 and 180 MHz, and may for example be in the 162 MHz band.

The temperature controller 175 is to execute temperature control algorithms and may be either software or hardware or a combination of both software and hardware. The temperature controller 175 may further comprise a component or module of the system controller 170 responsible for management of the system 100 through a central processing unit (CPU) 172, memory 173, and input/output (I/O) interfaces 174. The temperature controller 175 is to output control signals affecting the rate of heat transfer between the pedestal 142 and a heat source and/or heat sink external to the plasma chamber 105. In the exemplary embodiment, the temperature controller 175 is coupled to a first heat exchanger (HTX) or chiller 177 and a second heat exchanger or chiller 178 such that the temperature controller 175 may acquire the temperature setpoint of the HTX/chillers 177, 178 and temperature 176 of the pedestal, and control a heat transfer fluid flow rate through fluid conduits 141 and/or 145 in the pedestal 142. One or more valves 185 (or other flow control devices) between the heat exchanger/chiller and fluid conduits in the pedestal may be controlled by temperature controller 175 to independently control a rate of flow of the heat transfer fluid to the plurality of fluid conduits 141, 145. In the exemplary embodiment therefore, two heat transfer fluid loops are employed. Other embodiments may include one or more heat transfer loops. Any heat transfer fluid known in the art may be used. The heat transfer fluid may comprise any fluid suitable to provide adequate transfer of heat to or from the substrate. For example, the heat transfer fluid may be a gas, such as helium (He), oxygen (O₂), or the like. However, in the exemplary embodiment the heat transfer fluid is a liquid, such as, but not limited to, Galden®, Fluorinert®, or ethylene glycol/water.

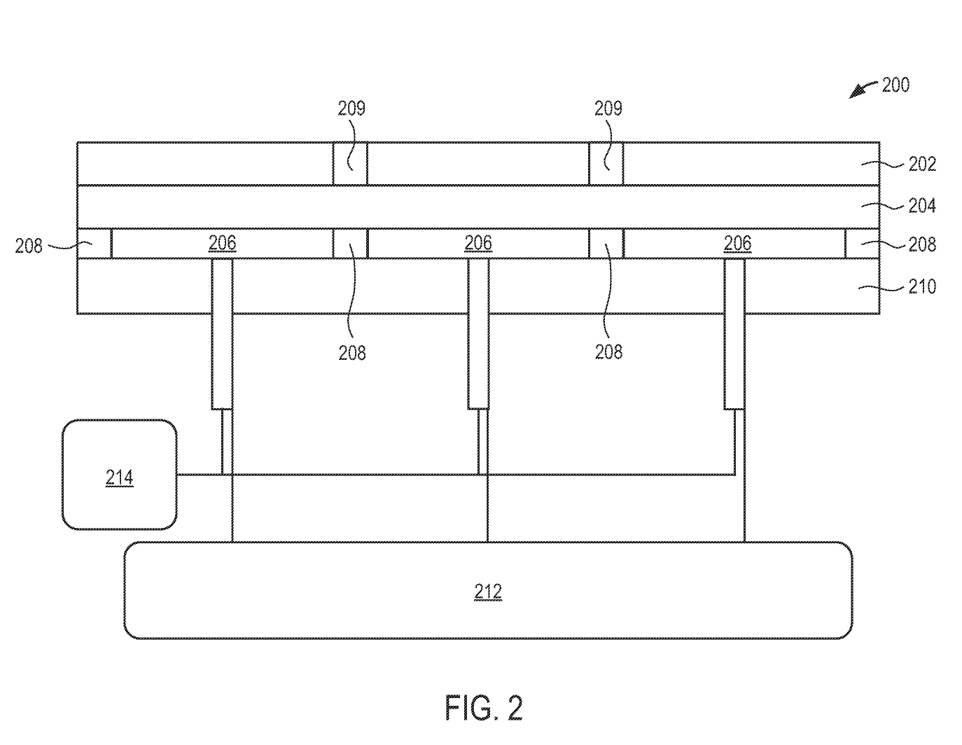

FIG. 2 is a cross-sectional diagram of a pedestal to support a workpiece during plasma processing in accordance with an embodiment of the invention. The pedestal 200 includes an electrostatic chuck (ESC) 202. The ESC 202 can be any chuck capable of holding a wafer or substrate during semiconductor processing, for example, a Johnsen Rahbek (JR) chuck, coulombic chuck, etc. ESCs can be mono-polar, bi-polar, or multi-polar. According to one embodiment, the ESC 202 includes a dielectric material over which a workpiece (not shown) is disposed. The dielectric material may be any known in the art. For example, in one embodiment, the dielectric material 143 is a ceramic (e.g., MN, Al₂O₃, etc.) capable of maintaining an electrostatic charge near the top surface to electrostatically clamp the workpiece during processing. In one exemplary embodiment, the ESC 202 includes a ceramic puck having at least one electrode (e.g., a mesh or grid) embedded in the ceramic to induce an electrostatic potential between a surface of the ceramic and a workpiece disposed on the surface of the ceramic when the electrode is electrified.

In one embodiment, the pedestal 200 further includes a gas distribution mechanism (not shown) to distribute gas between the top ESC surface and the workpiece. Gas between the top ESC surface and the workpiece can create pressure for thermal conduction with the workpiece. According to one embodiment, a gap for gas behind the workpiece is in the range of 10-50 μm. As described below, the gas between the ESC surface and the workpiece can be contained in compartments which are independently controllable. In one embodiment, the amount of contact between the ESC surface and the wafer can be varied to affect the temperature zones. For example, in one embodiment, the contact between the workpiece and the ESC surface is variable between 2-100%.

In the embodiment illustrated in FIG. 2, the ESC 202 is disposed above one or more heating elements 204. The one or more heating elements 204 can include AC heating elements, DC electrodes, and/or any other type of heater element capable of providing heat flux for heating the ESC 202. A single heating element can provide more uniform heating than multiple heating elements, according to one embodiment. The pedestal 200 also includes a cooling base 210 disposed below the ESC 202. According to one embodiment, the cooling base 210 is capable of substantially uniform cooling of a surface of the cooling base. As mentioned above with respect to FIG. 1, the cooling base can include conduits/channels for a heat transfer fluid or gas, as described above. The cooling base 210 can include any number of paths, showerheads, radial pattern(s), counter flow, and/or any other cooling base features. The cooling base 210 can include a single zone (which can enable substantially uniform cooling), or multiple zones (which can enable adjustment flexibility). According to one embodiment, the cooling base 210 is made from a metal such as aluminum.

In one embodiment, a plurality of gaps or compartments 206 are disposed between the heater element(s) 204 and the cooling base 210. The compartments 206 can be disposed over a top surface of the cooling base 210, or integrated into a top section of the cooling base 210, according to embodiments. During operation of a plasma etch system including the pedestal 200, each of the compartments 206 typically contain a gas. For example, the compartments 206 can contain helium, hydrogen, argon, nitrogen, or any other gas with suitable thermal conductivity. As illustrated, in one embodiment, gas seals 208 between the heater element(s) 204 and the cooling base 210 separate the compartments 206. The gas seals provide isolation between the compartments 206. The compartments 206 have a sufficiently short height to enable changes in gas composition and/or pressure to change the thermal conductivity of the compartment. For example, the compartments can have a height of 50 μm.

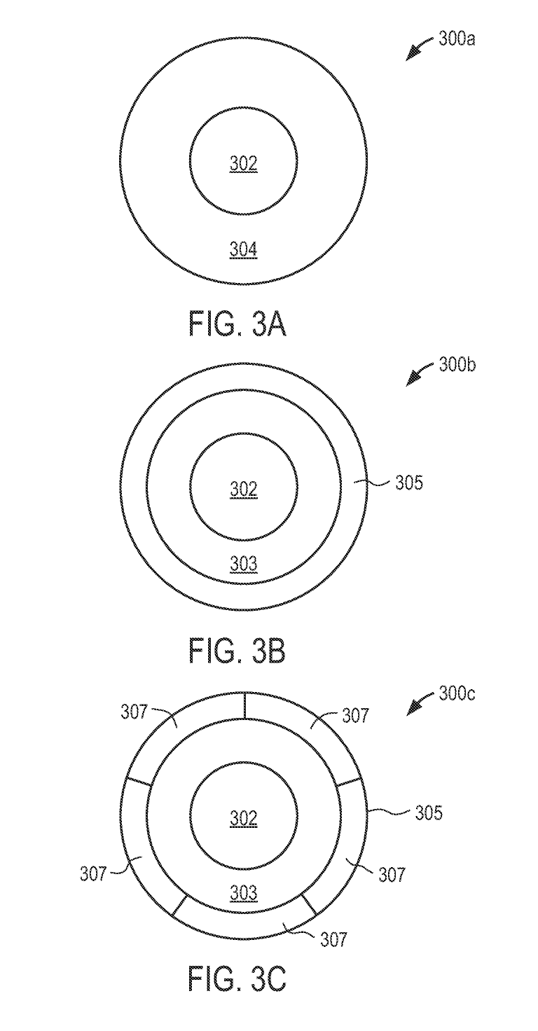

One or more controllers 212 and 214 can independently adjust the thermal conductivity of the gas in the compartments 206 to create different temperature zones on the ESC. For example, the compartments 206 in FIG. 2 correspond to the temperature zone pattern 300a of FIG. 3A. The controller(s) 212 and 214 can adjust the thermal conductivity of the compartments 206 by adjusting, for example, the gas pressure in the compartments 206, and/or by controlling the gas composition in the compartments 206. In one embodiment, the controller(s) 212 and 214 independently adjust the pressure of the compartments 206 to be between 1-50 torr. In one embodiment, the controller(s) 212 and 214 independently adjust the pressure of the compartments 206 to be between 1-10 torr. Increasing the gas pressure results in a higher thermal conductivity, and lowering the gas pressure results in a lower thermal conductivity. In an embodiment with heating element(s) and variable thermal conductivity compartments, the heating element(s) can provide a constant heat source (which is substantially independent of RF power applied in the chamber) to effectively generate the different temperature zones based on the thermal conductivity of the compartments 206. As indicated above, a pedestal with independently pressure controllable compartments such as the embodiment illustrated in FIG. 2 can minimize power consumption. For example, the pedestal 200 in FIG. 2 can control the pressure in one or more of the compartments 206 to a low value to minimize heat transfer. By minimizing heat transfer, pedestal 200 can operate in an ‘idle state’ and maintain the temperature of the ESC surface (and therefore workpiece) at a relatively steady temperature with minimal power consumption.

The thermal breaks 209 can include gaps to contain gas or a vacuum, or another thermally insulating material to reduce temperature cross talk amongst zones. As illustrated, the thermal breaks 209 are located in the ESC 202. However, the thermal breaks 209 may be located in the section with the heating elements 204 instead of, or in addition to being located in the ESC 202. For example, in one embodiment where the heating elements 204 and the ESC 202 are combined in a monolithic ceramic structure, the thermal breaks are located in that combined heating element and ESC structure.

The thermal breaks 209 can include a sealing band to contain a gas or vacuum of the thermal break. In one embodiment where the thermal breaks 209 include an air gap to contain a gas, the controller(s) 212 and 214 can further adjust the thermal conductivity of the thermal breaks 209. For example, in one embodiment, the thermal breaks 209 separating the independently pressure-controlled compartments 206 are controllable to different pressures. In one embodiment, the gas composition in the thermal breaks 209 is controllable. The controller(s) 212 and 214 control the gas pressure and/or gas composition in the thermal breaks 209 via valves and tubes fed through the gas seal regions 208, in accordance with an embodiment. According to one embodiment, the thermal breaks 209 are approximately 50 μm thick. In other embodiments, the thermal breaks 209 can have a thickness greater or less than 50 μm that minimizes thermal cross talk. The illustrated thermal breaks 209 have the same width, however, other embodiments can include thermal breaks having different dimensions. Additionally, the thermal breaks 209 are illustrated as having the same width as the gas seals 208, however, the thermal breaks 209 and gas seals 208 may have different dimensions. The thermal breaks 209 and/or any other compartment walls can be polyimide (PI), a ceramic, or any other suitable material.

In one embodiment, the pedestal can include an additional plurality of compartments (not shown) disposed above the ESC which are independently controllable to different thermal conductivities. In embodiments with an additional plurality of compartments above the ESC, the thermal conductivity can be adjusted in the same ways as described with respect to the compartments 206 between the heating elements(s) 204 and the cooling base 210.

As mentioned briefly above, the ESC 202, the one or more heating elements 204, and the plurality of compartments 206 can be comprised in a monolithic body (e.g., integrated into the bulk ceramic of the ESC 202). Alternatively, the heating element(s) 204 and/or the compartments can be manufactured separately and integrated by, for example, bonding, mechanical clamping, or other means of coupling the heating element(s) 204 and compartments 206 with the ESC 202. In one embodiment, the compartments 206 are comprised in the cooling base 210.

Returning to the controller(s) 212 and 214, the gas pressure and/or composition can be controlled by a standard control device supplying gas to the compartments 206. For example, the pedestal 200 can include a dedicated pressure controller per zone, a multiplexing valve array, a rotary valve assembly, or some combination thereof. The embodiment illustrated in FIG. 2 includes the gas pressure controller 212, which includes a multiple valve array. A multiplexer 214 determines which valves to open (and therefore, which compartment(s) 206 to adjust) based on one or more ‘select’ inputs (not shown). As described above, the controller(s) 212 and 214 can independently adjust the thermal conductance of each of the compartments 206, which generates temperature zones on the ESC surface.

Thus, in one embodiment, one or more controllers generate a plurality of temperature zones on the ESC surface based on maintaining different pressures in different compartments and/or thermal breaks. The temperature zones are also affected by heating by the heating element(s), the configuration of the compartments, and cooling by the cooling base of the interface between the cooling base and the plurality of compartments. The temperature zones can enable compensation for temperature non-uniformities to keep a workpiece at a uniform temperature, or can enable different temperature zones on the workpiece (e.g., heating the edge of the workpiece to a different temperature than the center to compensate for chemistry differences).

FIGS. 3A-3C are top-down views of exemplary temperature zones on an electrostatic chuck (ESC) surface, in accordance with embodiments of the invention. FIGS. 3A, 3B, and 3C illustrate three different configurations of temperature zones, although any configuration and number of zones are possible. A greater number of zones permits finer temperature control of the workpiece.

FIG. 3A illustrates a top-down view of an ESC surface 300a with two different temperature zones: an internal or inner zone 302 and an external or outer zone 304. In this illustrated embodiment, the inner zone 302 is circular (i.e., substantially circular), and the outer zone 304 is annular (i.e., substantially annular). FIG. 3B illustrates a top-down view of an ESC surface 300b with three temperature zones. In addition to an inner zone 302 and an outer zone 305, the ESC surface 300b has a middle annular temperature zone in between the outer annular temperature zone and the inner circular zone. In addition to different zones at different radii, the ESC surface can have temperature zones azimuthally. For example, FIG. 3C illustrates a top-down view of an ESC surface 300c with six different temperature zones. Like the ESC surface 300b in FIG. 3B, the ESC surface 300c includes an inner zone 302 and a middle zone 303. Additionally, the embodiment illustrated in FIG. 3C includes an outer substantially annular zone which is azimuthally divided into smaller sub-zones 307. A configuration with the outer zones 307 could be beneficial for systems having chambers with asymmetries (e.g., a door on one side, but not on another side). Azimuthally segmented annular temperature zones at the edge of an ESC (such as zones 307) can enable compensation for temperature non-uniformities caused by such chamber features. Other configurations with azimuthally segmented zones are also possible. For example, one embodiment includes an inner circular zone such as 302 of FIG. 3A, and an outer annular zone 304 which is azimuthally segmented. Embodiments can include any number of azimuthally segmented sub-zones (e.g., 2, 3, 4, 5, or more than 5 azimuthally segmented sub-zones).

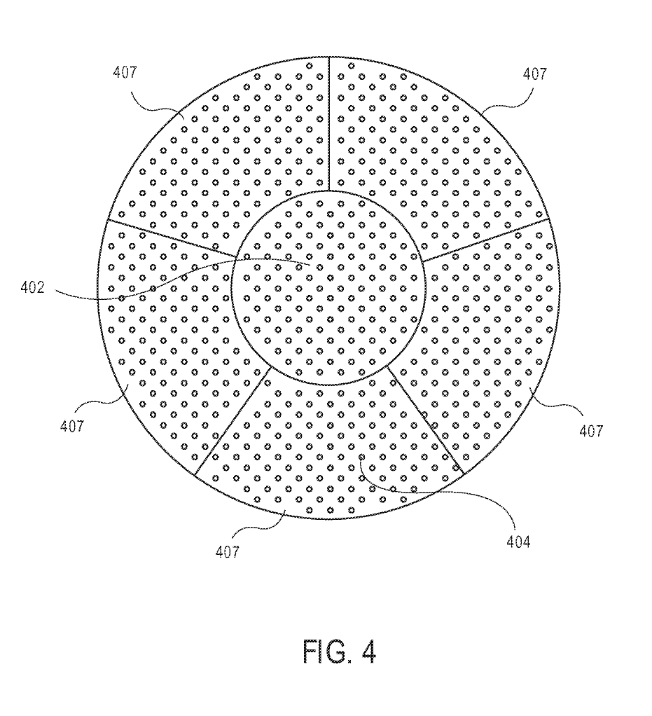

FIG. 4 is a top-down view of independently pressure-controllable compartments, in accordance with embodiments of the invention. As illustrated in FIG. 4, according to one embodiment, the compartments 402 and 407 are patterned.

According to one embodiment, a bottom or top surface of a compartment is patterned. The pattern can include multiple protrusions or high points (also known as mesas), which can be flat, rounded, or in another shape. For example, the compartments 402 and 407 are patterned with protrusions 404. The protrusions can be, for example, 10-50 μm high. In one embodiment, the protrusions have a diameter of 0.55 mm. In another embodiment, the protrusions have a diameter of 0.5-1 mm. Other embodiments can include other diameters and heights suitable for the size of the gas compartments.

In one embodiment, a method of making the protrusions includes applying a mask to the surface to be patterned, and patterning or embossing the surface via bead blasting, sand blasting, etching, or any other process capable of generating the desired pattern. In another embodiment, the plurality of protrusions are generated via deposition of materials on the compartment surface. A compartment which comprises a gap with a patterned surface has the advantage of being easy to manufacture while at the same time permitting a very small gap for efficient and effective heat transfer. However, other embodiment may include compartments which are not patterned, or have different patterns than the pattern depicted in FIG. 4.

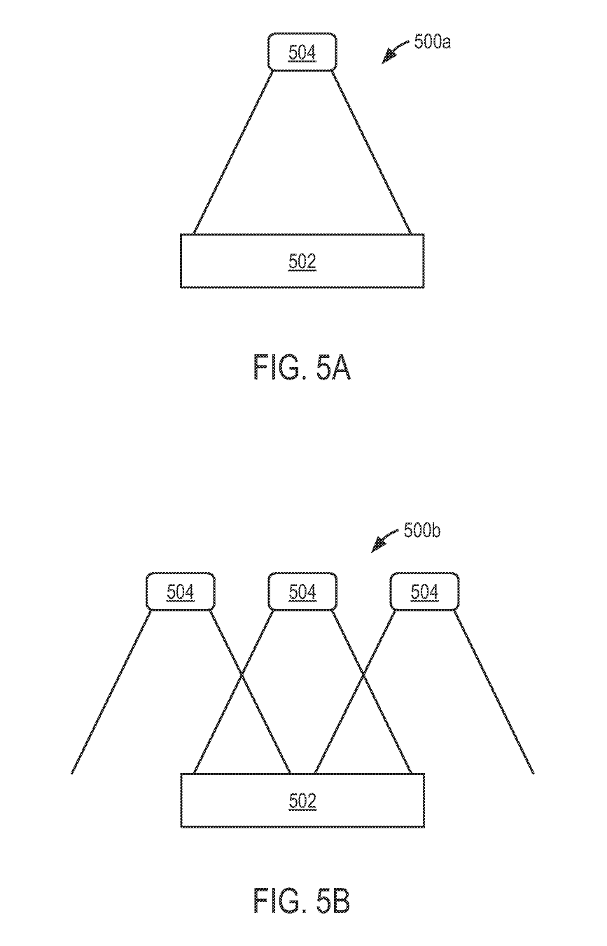

FIGS. 5A and 5B are block diagrams illustrating systems with top-down temperature sensors, according to embodiments of the invention. Traditional temperature measurement techniques include embedding probes in the ESC or other parts of the pedestal. Such traditional temperature probes include, for example, resistance temperature detectors (RTD), thermocouples, Fluoroptic thermometers, infrared (IR) sensors, or any other temperature probes capable of being integrated into the pedestal. Such sensors measure the temperature of the pedestal (e.g., the temperature of the ESC), and therefore only indirectly measure the temperature of the wafer or substrate being processed. A temperature difference typically exists between the ESC and the wafer, and therefore measurements of the ESC temperature may not accurately reflect the temperature of the wafer. Additionally, including sensors within the ESC or other parts of the pedestal can cause additional temperature non-uniformities due to, for example, holes or gaps to accommodate the sensors and/or cables.

As illustrated in FIGS. 5A and 5B, a top down measurement system can detect the temperature of the wafer rather than (or in addition to) relying on indirect temperature measurements of the ESC. In one embodiment, a plasma processing system includes one or more temperature sensors disposed above the pedestal to detect a temperature of the workpiece. The system 500a of FIG. 5A is a block diagram illustrating a single overhead temperature sensor 504 capable of detecting the temperature of a workpiece 502 and/or ESC over which the workpiece is disposed. The system 500b of FIG. 5B is a block diagram illustrating multiple overhead temperature sensors 504. Although systems 500a and 500b illustrate overhead temperature sensors, other embodiments can include side temperature sensors in addition to, or in place of, overhead temperature sensors. Similar to overhead temperature sensors, side temperature sensors can measure the temperature of the wafer directly. In one embodiment, the number of overhead and/or side temperature sensors is equal to the number of temperature zones. Other embodiments can include more or fewer temperature sensors than temperature zones.

In one such embodiment, temperature sensors 504 include infrared (IR) cameras. In one embodiment, temperature sensors 504 include a scanning laser system. Other embodiments can include any other type of temperature sensor capable of measuring temperature at a distance from the wafer. Systems with such overhead and/or side temperature sensors can collect data from multiple sensors, and process the collected data to generate an image of the wafer. As mentioned above, the temperature sensor(s) 504 can be used with standard temperature probes which measure the ESC temperature (e.g., temperature sensors embedded in the pedestal). The image of the wafer—and/or other temperature data collected from embedded probes—can be used to determine temperature variations on the wafer, and determine how to independently control the temperature zones on the ESC surface. For example, temperature data collected from overhead temperature sensors 504 can be used by the controllers 212 and 214 of FIG. 2 to control the thermal conductivities of the compartments 206. According to one embodiment, a controller can select one or more areas of the workpiece to take temperature measurements from to use for controlling the temperature zones of the ESC surface. For example, the temperature at the edge of the wafer, the center of the wafer, and/or the temperature at some other area(s) of the wafer can be used to determine adjustments to the temperature zones of the ESC surface.

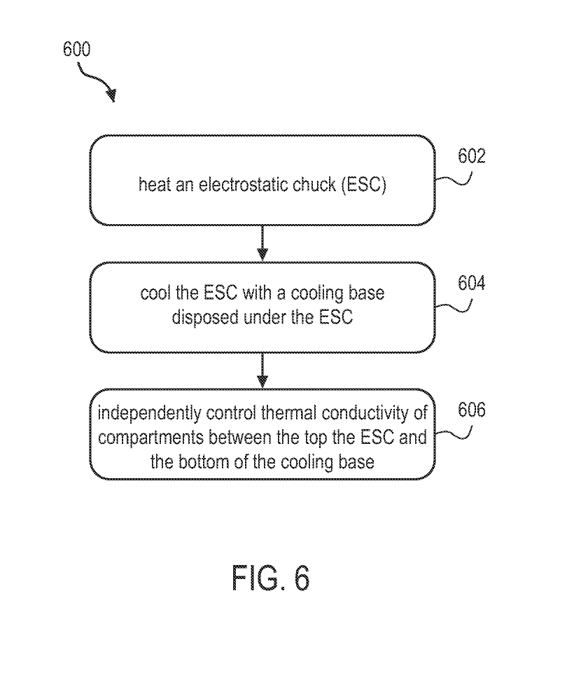

FIG. 6 is a flow diagram of a method of controlling the temperature of a workpiece during plasma processing according to embodiments of the invention. The method 600 begins at operation 602 with heating an electrostatic chuck (ESC). For example, the method 600 can include heating the ESC 202 of FIG. 2 with heating element(s) 204. Heating the ESC can also involve heating due to processing a workpiece disposed over the ESC (e.g., due to plasma etch processing). At operation 604, the method involves cooling the ESC with a cooling base. The cooling base is disposed under and set apart from the ESC by compartments. For example, the cooling base 210 of FIG. 2 can provide a heat sink for the ESC 202. The cooling base 210 in FIG. 2 illustrates an embodiment where the cooling base is separated from the ESC by compartments and/or thermal breaks. At operation 606, one or more controllers independently control the thermal conductivity of the compartments between the ESC and the cooling base. For example, the controllers 212 and 214 can independently control the gas composition and pressure of the compartments 206 to generate temperature zones on the ESC surface. The generated temperature zones can enable fine control of the temperature of a workpiece held by the ESC during processing.

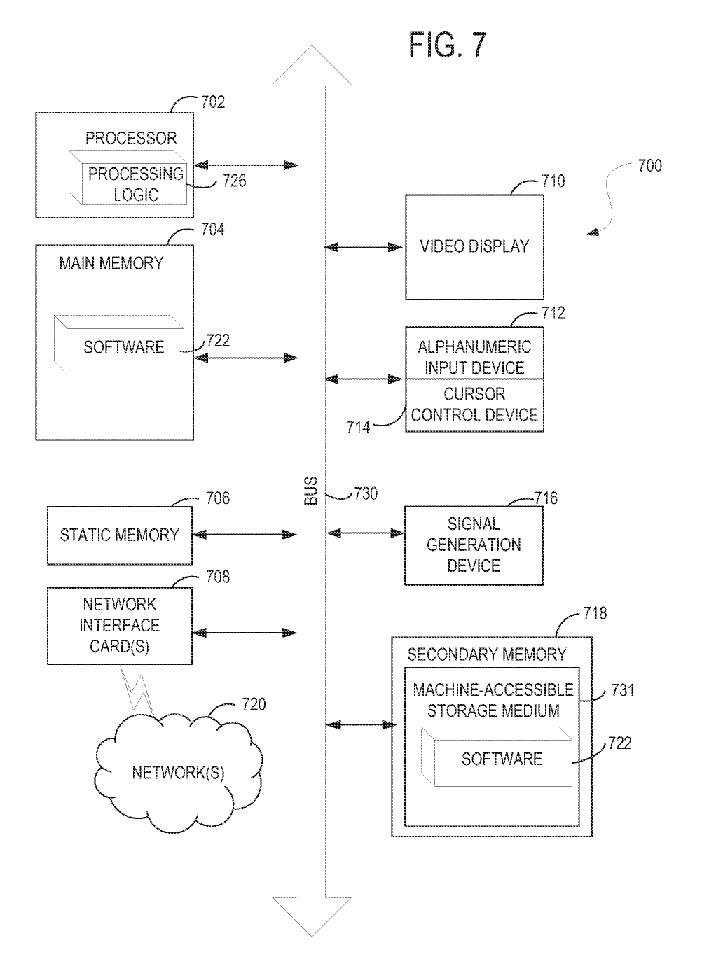

FIG. 7 illustrates a block diagram of an exemplary computer system for performing methods described herein, in accordance with an embodiment of the present invention. The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, etc. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations and steps discussed herein.

The computer system 700 may further include a network interface device 708. The computer system 700 also may include a video display unit 710 (e.g., a liquid crystal display (LCD) or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 731 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, optical and magnetic media, and other non-transitory machine-readable storage medium.

It is to be understood that the above description is intended to be illustrative, and not restrictive. For example, while flow diagrams in the figures show a particular order of operations performed by certain embodiments of the invention, it should be understood that such order is not necessarily required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. A pedestal to support a workpiece during plasma processing, the pedestal comprising:
an electrostatic chuck (ESC) having a top surface over which the workpiece is to be disposed;
one or more heating elements disposed under the top surface of the ESC;
a cooling base disposed under the ESC;
a plurality of compartments separated by gas seals and disposed between the top surface of the ESC and the cooling base, the plurality of compartments independently controllable to different pressures;
wherein one or more controllers is to generate a plurality of temperature zones on the top surface of the electrostatic chuck based on maintaining a first pressure in a first of the plurality of compartments and a second pressure in a second of the plurality of compartments, the plurality of temperature zones comprising an inner circular zone and an outer annular zone azimuthally divided into a plurality of temperature sub-zones.

2. The pedestal of claim 1, wherein:
the one or more heating elements comprise AC heaters to heat the ESC; and
the cooling base comprises channels for a cooling gas or liquid to cool an interface between the cooling base and the plurality of compartments to a substantially uniform temperature.

3. The pedestal of claim 1, wherein the plurality of temperature zones further comprises a middle annular temperature zone in between the outer annular zone and the inner circular zone.

4. The pedestal of claim 1, wherein each of the plurality of compartments comprises a substantially planar surface and a surface patterned with a plurality of protrusions.

5. The pedestal of claim 1, further comprising thermal breaks disposed between the top surface of the ESC and a bottom of a section comprising heating elements, wherein the thermal breaks comprise air gaps to contain a gas and are independently controllable to different pressures.

6. The pedestal of claim 1, wherein the ESC, the one or more heating elements, and the plurality of compartments are comprised in a monolithic body.

7. The pedestal of claim 1, wherein the plurality of compartments are disposed in a layer between the one or more heating elements and the cooling base.

8. The pedestal of claim 1, wherein the plurality of compartments are comprised in a top surface of the cooling base.

9. The pedestal of claim 1, further comprising one or more second compartments disposed above the top surface of the ESC, the one or more second compartments independently controllable to different pressures.

10. The pedestal of claim 1, wherein the plurality of compartments are independently controllable to contain different gases having different thermal conductivities.

11. A plasma etch system comprising:
a vacuum chamber;
a gas source to supply a gas to the vacuum chamber;
a pedestal comprising:
an electrostatic chuck (ESC) having a top surface over which a workpiece is to be disposed;
one or more heating elements disposed under the top surface of the ESC;
a cooling base disposed under the ESC;
a plurality of compartments separated by gas seals and disposed between the top surface of the ESC and the cooling base, the plurality of compartments independently controllable to different pressures,
one or more controllers to generate a plurality of temperature zones on the top surface of the electrostatic chuck based on maintaining a first pressure in a first of the plurality of compartments and a second pressure in a second of the plurality of compartments, the plurality of temperature zones comprising an inner circular zone and an outer annular zone azimuthally divided into a plurality of temperature sub-zones; and
an RF generator coupled to at least one of the vacuum chamber, gas source, or pedestal.

12. The plasma etch system of claim 11, further comprising:
one or more temperature sensors disposed above the pedestal to detect a temperature of the workpiece;
wherein the one or more controllers is to control the first pressure in the first of the plurality of compartments and the second pressure in the second of the plurality of compartments based on the temperature of the workpiece detected by the one or more temperature sensors disposed above the pedestal.

13. The plasma etch system of claim 11, wherein the plurality of temperature zones further comprises a middle annular temperature zone in between the outer annular temperature zone and the inner circular zone.

14. The plasma etch system of claim 11, further comprising thermal breaks disposed between the top surface of the ESC and a bottom of a section comprising heating elements, wherein the thermal breaks comprise air gaps to contain a gas and are independently controllable to different pressures.

15. A method of controlling the temperature of a workpiece during plasma processing, the method comprising:
heating an electrostatic chuck (ESC) having a top surface over which the workpiece is to be disposed with one or more heating elements disposed under the top surface of the ESC;
cooling the ESC with a cooling base disposed under the ESC; and
independently controlling, with one or more pressure controllers, pressure in a plurality of compartments disposed between the top surface of the ESC and the cooling base, wherein independently controlling pressure comprises controlling pressure in a first of the plurality of compartments to a first pressure and in a second of the plurality of compartments to a second pressure to generate a plurality of temperature zones on the top surface of the electrostatic chuck, the plurality of temperature zones comprising an inner circular zone and an outer annular zone azimuthally divided into a plurality of temperature sub-zones.

16. The method of claim 15, wherein thermal breaks disposed between the top surface of the ESC and a bottom of a section comprising heating elements comprise air gaps to contain a gas, the method further comprising independently controlling, with the one or more pressure controllers, the gas in the thermal breaks to different pressures.

17. The method of claim 15, wherein the plurality of temperature zones generated via independently controlling the pressure in the plurality of compartments further comprises a middle annular temperature zone in between the outer annular zone and the inner circular zone.

18. The method of claim 15, wherein each of the plurality of compartments comprises a substantially planar surface and a surface patterned with a plurality of protrusions.

19. The method of claim 15, further comprising one or more second compartments disposed above the top surface of the ESC, the one or more second compartments independently controllable to different pressures.

20. The method of claim 15, further comprising independently controlling the plurality of compartments to contain different gases.
